(19) United States
(12) Patent Application Publication
(10) Pub. No.: US 2026/0179667 A1
(43) Pub. Date: Jun. 25, 2026

(54) MEMORY DEVICE WITH FERROELECTRIC TRANSISTOR AND CAPACITOR CONNECTED IN SERIES, RELATED ELECTRONIC CIRCUIT, PROGRAMMING METHOD AND READING METHOD

(71) Applicant: Commissariat à l’Energie Atomique et aux Energies Alternatives, Paris (FR)

(72) Inventors: Julien BORREL, Grenoble Cedex 9 (FR); Mathieu FAYE, Grenoble Cedex 9 (FR); Sebastien RICAVY, Grenoble Cedex 9 (FR)

(73) Assignee: Commissariat à l’Energie Atomique et aux Energies Alternatives, Paris (FR)

(21) Appl. No.: 19/428,971

(22) Filed: Dec. 22, 2025

(30) Foreign Application Priority Data
Dec. 24, 2024 (FR) FR2415234

(51) Int. Cl. G11C 11/22

(52) U.S. Cl. CPC G11C 11/221; G11C 11/2273; G11C 11/2275

(57) ABSTRACT

A memory device including a ferroelectric field-effect transistor including a gate electrode and first and second conduction electrodes; a ferroelectric capacitor including first and second charge electrodes; the transistor and the ferroelectric capacitor being connected according to a first connection configuration, wherein the first conduction electrode is connected to a reference potential and the second conduction electrode is connected to the first charge electrode, or according to a second connection configuration, wherein the first conduction electrode is connected to the first charge electrode and the second conduction electrode is connected to the second charge electrode.

### CROSS-REFERENCE TO RELATED APPLICATIONS

This application is a U.S. non-provisional application claiming the benefit of French Application No. 24 15234, filed on Dec. 24, 2024, which is incorporated herein by reference in its entirety.

### FIELD

The present invention relates to a memory device.

The invention also relates to an electronic circuit comprising a plurality of such memory devices, as well as a programming method for such a memory device and a reading method for such a memory device.

### BACKGROUND

Traditionally, a computing unit such as a processor, a CPU (Central Processing Unit), for example, and a storage unit such as a memory, are physically separate and connected via a data bus, which involves a significant data transfer, via this bus, between the computing unit responsible for calculation operations and the storage unit responsible for storing operands, then of the result of the calculation operations. The bandwidth of the data bus then often becomes a limiting factor, also known as the von Neumann bottleneck.

To mitigate this limiting factor, performing logical operations directly in the memory is known, this technological field also being called PIM (Processing In Memory).

A sub-domain of the PIM field is stateful logic, which consists of performing logical operations directly on memory points, without needing to read and process the information stored there. The logical operation is done naturally and automatically, depending on how the memory points are connected to each other.

However, this technological sub-domain uses resistive components, and thus involves significant consumption of current.

### SUMMARY

The aim of the invention is to propose a memory device that enables a logical operation to be performed while having a more limited consumption of current.

To this end, the invention relates to a memory device comprising:
a ferroelectric field-effect transistor including a gate electrode and first and second conduction electrodes;
a ferroelectric capacitor including first and second charge electrodes;
the transistor and the ferroelectric capacitor being connected according to a configuration chosen from a first connection configuration, wherein the first conduction electrode of the transistor is configured to be connected to a reference potential and the second conduction electrode is connected to the first charge electrode of the ferroelectric capacitor, and a second connection configuration, wherein the first conduction electrode of the transistor is connected to the first charge electrode of the ferroelectric capacitor and the second conduction electrode of the transistor is connected to the second charge electrode of the ferroelectric capacitor.

The memory device according to the invention then enables a logical operation to be performed directly in the memory, between a first value stored in the transistor and a second value stored in the capacitor, with the transistor being a ferroelectric field-effect transistor and the capacitor being a ferroelectric capacitor, while having a low consumption of current.

According to another advantageous aspect of the invention, the memory device comprises the following feature:
the transistor is chosen from the group consisting of a ferroelectric gate oxide field-effect transistor and a field-effect transistor with ferroelectric capacity connected to the gate electrode.

The invention also relates to an electronic circuit comprising a plurality of memory devices, each as defined above.

According to another advantageous aspect of the invention, the electronic circuit comprises one or more of the following features, taken individually or in any technically possible combination:
the electronic circuit comprises a substrate, a set of level(s) close to the substrate, called front end, for the connection of electronic component(s), and a set of level(s) distant from the substrate, called back end;
the transistor preferably being included in the front end, with the ferroelectric capacitor being included in the back end; or
the transistor and the ferroelectric capacitor being included in the back end;
when the transistor is a field-effect transistor with ferroelectric capacity connected to the gate electrode further including an additional capacitor forming the ferroelectric capacity, then the additional capacitor is included in the back end;
the electronic circuit is comprised of at least one block of several memory devices;
a first block among the at least one block preferably being formed of memory devices where the transistors and ferroelectric capacitors are connected according to the first connection configuration and a second block among the at least one block being formed of memory devices where the transistors and ferroelectric capacitors are connected according to the second connection configuration;
a block among the at least one block again preferably including a first sub-block comprising only the transistors, a second sub-block including only the ferroelectric capacitors, and a connection module of the second sub-block to the first sub-block, the connection module including a multiplexer to select a connection configuration, chosen from the first connection configuration and the second connection configuration, for each memory device formed of a transistor of the first sub-block and a ferroelectric capacitor of the second sub-block.

The invention also relates to a programming method for a memory device as defined above, comprising a programming phase during which a first input potential is applied to the gate electrode to write a first value, and a second input potential is applied to the second charge electrode to write a second value;
the first conduction electrode and the first charge electrode being further connected to a reference potential when the transistor and the ferroelectric capacitor are connected according to the second connection configuration.

According to other advantageous aspects of the invention, the programming method comprises one or more of the following features, taken individually or in any technically possible combination:
during the programming phase, the transistor is polarized at a low level if the first input potential is greater than a programming potential, and at a high level if the first input potential is less than the opposite of the programming potential; and
during the programming phase, the ferroelectric capacitor is polarized at a high level if the second input potential is greater than the programming potential, and at a low level if the second input potential is less than the opposite of the programming potential,
with the first input potential comprised between a threshold potential of the transistor and the programming potential when the transistor and the ferroelectric capacitor are connected according to the first connection configuration; and
with the first input potential less than the threshold potential of the transistor when the transistor and the ferroelectric capacitor are connected according to the second connection configuration.

The invention also relates to a reading method for a memory device as defined above, the memory device being configured to perform a logical function between a first value and a second value previously written in the memory device via a programming method as defined above, the reading method comprising a reading phase during which the gate electrode is connected to an electrical ground, and during which the opposite of the programming potential is applied to the second charge electrode, a result of the logical function corresponding to a current value through the memory device.

According to other advantageous aspects of the invention, the reading method comprises one or more of the following features, taken individually or in any technically possible combination:
the result of the logical function is a binary value determined via the comparison of the current value through the memory device with a predefined current threshold;
the result of the logical function preferably being equal to 1 if said current value is greater than the predefined current threshold, and 0 otherwise;
when the transistor and the ferroelectric capacitor are connected according to the first connection configuration, the logical function is an AND function between the first and second values for nominal values of the first and second input potentials, and the logical function is a NOR function between the first and second values for complementary values of the first and second input potentials, the complementary values being the opposite of said nominal values;
when the transistor and the ferroelectric capacitor are connected according to the second connection configuration, the logical function is an OR function between the first and second values for nominal values of the first and second input potentials, and the logical function is a NAND function between the first and second values for complementary values of the first and second input potentials, the complementary values being the opposite of said nominal values;
the first value, programmed in the transistor during the programming phase, corresponds to a transistor polarization level resulting from the application of the first input potential to the gate electrode;
the first value preferably being equal to 1 if the transistor polarization is at a low level, and 0 if said polarization is at a high level;
the second value, programmed in the ferroelectric capacitor during the programming phase, corresponds to a polarization level of the ferroelectric capacitor resulting from the application of the second input potential to the second charge electrode;
the first conduction electrode and the first charge electrode being further connected to a reference potential when the transistor and the ferroelectric capacitor are connected according to the second connection configuration;
the second value preferably being equal to 1 if the polarization of the ferroelectric capacitor is at a high level, and 0 if said polarization is at a low level.

### BRIEF DESCRIPTION OF THE DRAWINGS

These features and advantages of the invention will become clearer upon reading the following description, given solely as a non-limiting example, and made with reference to the attached drawings, wherein:

FIG. 1 is a schematic representation of an electronic circuit according to the invention, including blocks of memory devices, each including a ferroelectric gate oxide field-effect transistor and a ferroelectric capacitor as well as a programming device and a reading device, connected to each of the respective programming and reading blocks of said memory devices;

FIG. 2 is a schematic representation of a respective memory device, according to a first connection configuration of the transistor and the capacitor; and

FIG. 3 is a view similar to that of FIG. 2, according to a second connection configuration of the transistor and the capacitor.

### DETAILED DESCRIPTION

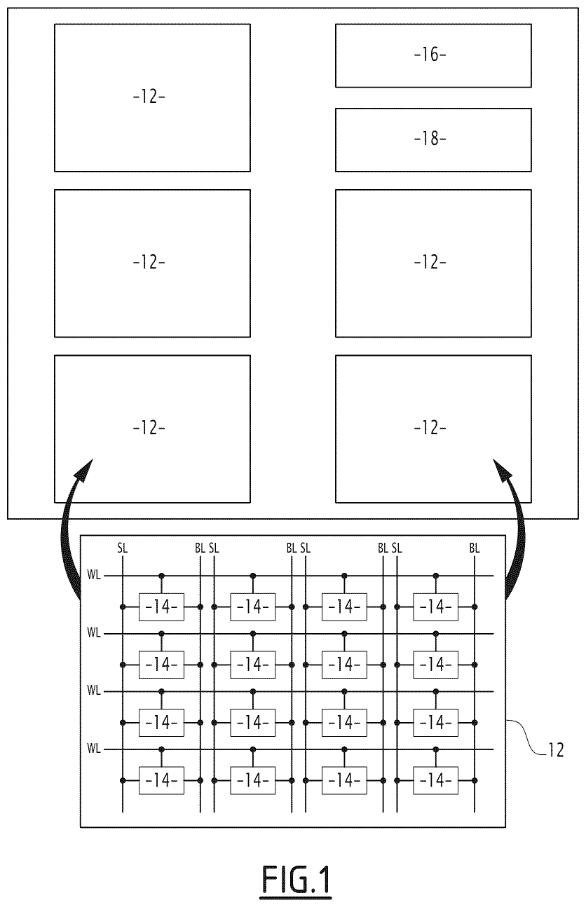

In FIG. 1, an electronic circuit 10 comprises one or more blocks 12, each including several memory devices 14, a programming device 16 and a reading device 18, with the respective programming device 16 and reading device 18 being connected to each of the memory device blocks 12.

The skilled person will observe that the number of block(s) 12 included in the electronic circuit 10 is variable and typically depends on the number of calculation operations to be performed per unit of time.

Each block 12 includes a plurality of memory devices 14, preferably arranged in a two-dimensional matrix, with the memory devices 14 then distributed in rows and columns.

Each block 12 also includes word lines WL, bit lines BL and source lines SL. The source lines SL and bit lines BL are advantageously parallel to each other, and the word lines WL are parallel to each other and perpendicular to the source lines SL and bit lines BL.

In the previous notations, a word line is referenced as WL (“Word Line”); the bit lines are referenced with the acronym BL (“Bit Line”) and the source lines are referenced with the acronym SL (“Source Line”).

The number of memory devices 14 within each respective block 12 is variable and also typically depends on the number of calculation operations to be performed per unit of time, as well as the architecture chosen for the electronic circuit 10, particularly the number of block(s) 12 included in the electronic circuit 10.

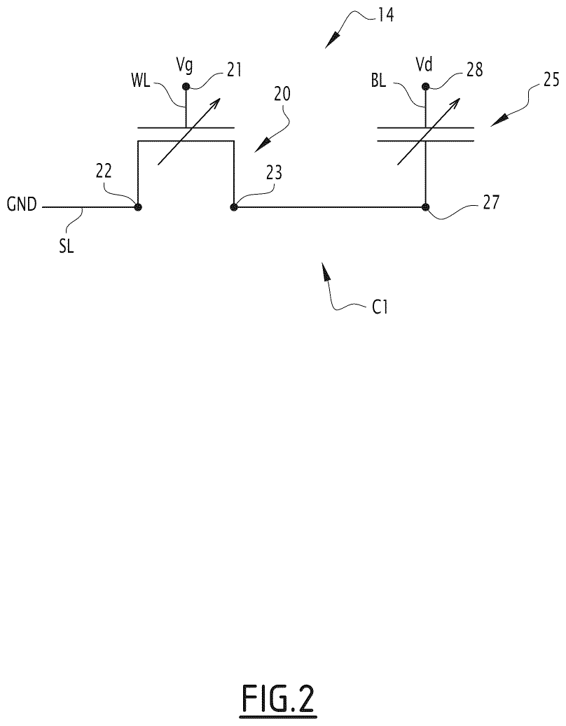

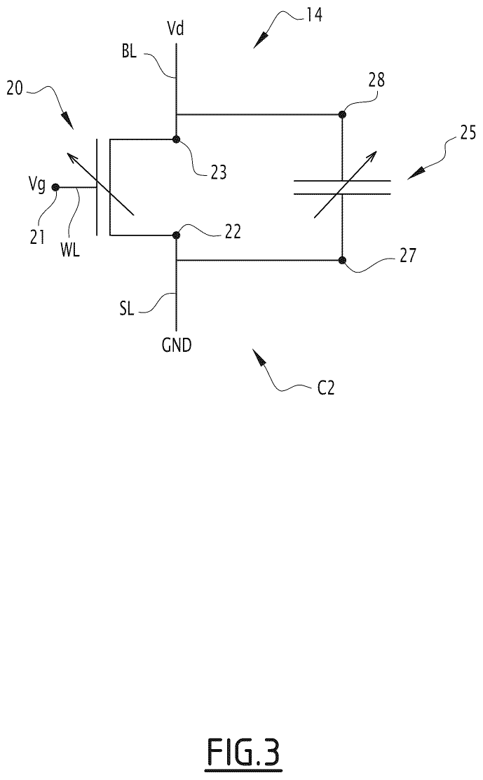

In the examples of FIGS. 2 and 3, the memory device 14 is connected to a respective word line WL; to a respective source line SL; and to a respective bit line BL.

In general, each memory device 14 is connected to a respective word line WLi, a respective source line SLj and a respective bit line BLj, where i and j are integer indices.

Each memory device 14 in the same row of the matrix shares the same word line WL, so the word lines WL can also be indexed with the index i.

The memory devices 14 in the same column share the same bit line BLj and the same source line SLj, so the bit lines BL and source lines SL can be indexed with the same index j.

The memory devices 14 in the same row are then selectable by a word line WL, and the memory devices 14 in the same column are connected to a pair of bit lines BL and source lines SL.

Each memory device 14 comprises a transistor 20, including a gate electrode 21 and first 22 and second 23 conduction electrodes, and a ferroelectric capacitor 25, including first 27 and second 28 charge electrodes. The first 22 and second 23 conduction electrodes are typically source and drain electrodes.

In the examples of FIGS. 2 and 3, the first conduction electrode 22 is a source electrode, and the second conduction electrode 23 is a drain electrode. In the examples of FIGS. 2 and 3, the gate electrode 21 is connected to the respective word line WL, the first conduction electrode 22 is connected to the respective source line SL and the second charge electrode 28 is connected to the respective bit line BL.

In the example of FIG. 2, the transistor 20 and the ferroelectric capacitor 25 are connected according to a first connection configuration C1, where the first conduction electrode 22 of the transistor 20 is configured to be connected to a reference potential GND and the second conduction electrode 23 is connected to the first charge electrode 27 of the ferroelectric capacitor 25.

The first connection configuration C1 is a configuration allowing a logical function of the AND type or of the NOR type in a complementary manner, as will be explained in more detail later during the description of the operation of the memory device 14.

In the example of FIG. 3, the transistor 20 and the ferroelectric capacitor 25 are connected according to a second connection configuration C2, where the first conduction electrode 22 of the transistor 20 is connected to the first charge electrode 27 of the ferroelectric capacitor 25 and the second conduction electrode 23 of the transistor 20 is connected to the second charge electrode 28 of the ferroelectric capacitor 25.

The second connection configuration C2 is a configuration allowing a logical function of the OR type or of the NAND type, in a complementary manner, as will also be explained in more detail later.

The programming device 16 is configured to program each memory device 14 by implementing the programming method according to the invention for each memory device 14 to be programmed, the programming method being described in more detail later.

The programming device 16 is advantageously configured to program several memory devices 14 at once, and preferably simultaneously, as long as it does not require applying two distinct voltage values at the same time on the same word line WL, or on the same bit line BL or on the same source line SL.

The reading device 18 is configured to read each memory device 14 by implementing the reading method according to the invention for each memory device 14 to be read, with the reading method described in more detail later.

The reading device 18 is advantageously configured to read several memory devices 14 at once, and preferably simultaneously, as long as it does not require applying or reading two distinct voltage values at the same time on the same word line WL, or on the same bit line BL or on the same source line SL.

The transistor 20 is a ferroelectric field-effect transistor and includes at least one field-effect transistor.

In the examples of FIGS. 2 and 3, the transistor 20 is a ferroelectric gate oxide field-effect transistor or FeFET (Ferroelectric Field-Effect Transistor).

In a variant, not shown, the transistor 20 is a field-effect transistor with ferroelectric capacity connected to the gate electrode, or FeMFET (FerroElectric Metal Field Effect Transistor). In this variant, the transistor 20 also includes an additional capacitor, not shown, forming the ferroelectric capacity.

The transistor 20 has a threshold potential, noted Vth, corresponding to the potential difference Vgs between its gate electrode and its source electrode, from which the transistor 20 is conductive.

Additionally, the electronic circuit 10 comprises a substrate, a set of level(s) close to the substrate, called front end, for the connection of electronic component(s), and a set of level(s) distant from the substrate, called back end, not shown. The front end is also noted FEOL (Front End Of Line), and the back end is also noted BEOL (Back End Of Line).

According to a first arrangement example, the transistor 20 is included in the front end, and the ferroelectric capacitor 25 is included in the back end.

According to a second arrangement example, the transistor 20 and the ferroelectric capacitor 25 are each included in the back end.

Additionally, when the transistor 20 is of the type of field-effect transistor with ferroelectric capacity connected to the gate electrode, or FeMFET, the additional capacitor forming the ferroelectric capacity is advantageously included in the back end, with the transistor being included in the back end or in the front end.

The operation of the memory device 14 according to the invention will now be described, starting with the programming method implemented by the programming device 16, then continuing with the reading method implemented by the reading device 18.

The programming method comprises a programming phase, during which a first input potential Vg is applied to the gate electrode 21, to write a first value, and a second input potential Vd is applied to the second charge electrode 28, to write a second value.

The first input potential Vg is applied to the gate electrode 21, to polarize the transistor 20. The first conduction electrode 22 is connected to an electrical ground, not shown. According to the second configuration C2, where the first charge electrode 27 is connected to the first conduction electrode 22, the first charge electrode 27 is also connected to the electrical ground during the programming phase. In other words, the voltage applied to the first conduction electrode 22, and possibly also to the first charge electrode 27 according to the second configuration C2, is substantially zero.

During the programming phase, the transistor 20 is then polarized at a low level if the first input potential Vg is greater than a programming potential Vprog of the transistor 20. Conversely, the transistor 20 is polarized at a high level if the first input potential Vg is less than the opposite −Vprog of said programming potential Vprog.

Thus, to store the first value in the transistor 20, the programming device 16 is configured to apply the first input potential Vg to the gate electrode 21 and to connect the first conduction electrode 22 to the electrical ground, and possibly also the first charge electrode 27 according to the second configuration C2, in order to polarize the transistor 20. The first input potential Vg applied is a strong positive voltage, meaning greater than the programming potential Vprog; or a strong negative voltage, meaning less than the opposite −Vprog of the programming potential.

The information stored in the transistor 20, i.e. the first value, then results in a high threshold potential Vth when the transistor 20 is polarized at a high level with Vg<−Vprog; and, conversely, a low threshold potential Vth when the transistor 20 is polarized at a low level with Vg>Vprog. These values of the first potential Vg are called nominal.

The second input potential Vd is applied to the second charge electrode 28, to polarize the ferroelectric capacitor 25, with the first charge electrode 27 being either connected to the second conduction electrode 23 of the transistor 20, according to the first connection configuration C1, or connected to the electrical ground, according to the second connection configuration C2.

During the programming phase, the ferroelectric capacitor 25 is then polarized at a low level if the second input potential Vd is greater than the programming potential Vprog, and at a high level if the second input potential Vd is less than the opposite −Vprog of the programming potential Vprog, with the first input potential Vg being between the threshold potential Vth and the programming potential Vprog when the transistor 20 and the ferroelectric capacitor 25 are connected according to the first connection configuration C1, or with the first input potential Vg less than the threshold potential Vth when the transistor 20 and the ferroelectric capacitor 25 are connected according to the second connection configuration C2.

The reading method of the memory device 14 according to the invention will now be described, which aims to perform the logical function between the first value, previously written in the transistor 20, and the second value, previously written in the ferroelectric capacitor 25, via the programming method according to the invention described above.

The reading method comprises a reading phase, during which the gate electrode 21 is connected to the electrical ground and the opposite −Vprog of the programming potential Vprog is applied to the second charge electrode 28, a result of the logical function corresponding to a current value through the memory device 14.

Thus, to read the memory device 14, and in particular to perform the logical function between the first and second values previously stored in the transistor 20 and the ferroelectric capacitor 25, respectively, by the programming device 16 during the programming phase, the reading device 18 is configured to put the transistor 20 in the non-polarized state and to bring the potential Vd applied to the second charge electrode 28 to −Vprog.

For the non-polarized state of the transistor 20, the gate electrode 21 and the first conduction electrode 22 are connected to the electrical ground. In other words, to put the transistor 20 in the non-polarized state, the reading device 18 is configured to connect the gate electrode 21 and the first conduction electrode 22 to the electrical ground. Thus, the voltages Vg, Vs applied to the gate electrode 21 and the first conduction electrode 22, respectively, are each substantially zero, i.e. Vg≈Vs≈0. The transistor 20 is then conducting or blocked, depending on the information previously stored in said transistor 20 during the programming phase, i.e. depending on the first value.

According to the first connection configuration C1, for a current to be measured through the memory device 14, both the transistor 20 must be in the state with the low threshold potential Vth to be conducting with the voltage Vg substantially zero, i.e. the transistor 20 must have been polarized at a low level with Vg>Vprog, and the ferroelectric capacitor 25 must switch during the reading phase, i.e. the ferroelectric capacitor 25 must have been polarized at a low level with Vd>Vprog.

The result of the logical function is then a binary value determined via the comparison of the current value through the memory device 14 with a predefined current threshold. The result of the logical function is equal to 1 if said current value is greater than the predefined current threshold, for example, and 0 otherwise.

The skilled person will understand that the first value written in the transistor 20 during the programming phase corresponds to the polarization level of the transistor 20 resulting from the programming phase, i.e. from the application of the first input potential Vg to the gate electrode 21. The first value is defined as equal to 1 if the polarization of the transistor 20 is at a low level, for example, and, correspondingly, 0 if said polarization is at a high level.

As a corollary, the second value written in the ferroelectric capacitor 25 during the programming phase corresponds to the polarization level of the ferroelectric capacitor 25 resulting from the programming phase, i.e. from the application of the second input potential Vd to the second charge electrode 28. The second value is defined as equal to 1 if the polarization of the ferroelectric capacitor 25 is at a low level, for example, and, correspondingly, 0 if said polarization is at a high level.

Also, according to the first connection configuration C1, the only case resulting in the flow of a current through the memory device 14, and thus a result of the logical function equal to 1, is when the transistor 20 has been polarized at a low level, meaning the first value is equal to 1, and, at the same time, the ferroelectric capacitor 25 has also been polarized at a low level, meaning the second value is equal to 1.

The skilled person will therefore understand that the logical function performed according to the first connection configuration C1 is the AND function between the first and second values.

The skilled person will also observe, as a corollary, that if the first and second values have complementary values of the first Vg and second Vd input potentials, with the complementary values being the opposite of the nominal values defined above, the logical function performed according to the first connection configuration C1 is then the NOR function between the first and second values, i.e. the complement of the AND function.

The first connection configuration C1 then enables performing the AND logical function or the NOR logical function.

According to the second connection configuration C2, to read the memory device 14, and in particular to perform the logical function between the first and second values, previously stored in the transistor 20 and the ferroelectric capacitor 25, respectively, by the programming device 16 during the programming phase, the reading device 18 is also configured to put the transistor 20 in the non-polarized state and to bring the potential Vd applied to the second charge electrode 28 to −Vprog.

According to the second connection configuration C2, for a current to be measured through the memory device 14, both the transistor 20 must be in the state with the low threshold potential Vth to be conducting with the voltage Vg substantially zero, i.e. the transistor 20 must have been polarized at a low level with Vg>Vprog, and/or the ferroelectric capacitor 25 must switch during the reading phase, i.e. the ferroelectric capacitor 25 must have been polarized at a low level with Vd>Vprog.

The result of the logical function is then also the binary value determined via the comparison of the current value through the memory device 14 with the predefined current threshold. The result of the logical function is equal to 1 if said current value is greater than the predefined current threshold, for example, and 0 otherwise.

Also, according to the second connection configuration C2, the only case resulting in the absence of a current flow through the memory device 14, and thus a result of the logical function equal to 0, is when the transistor 20 has been polarized at a high level, meaning the first value is equal to 0, and at the same time the ferroelectric capacitor 25 has also been polarized at a high level, meaning the second value is equal to 0.

The skilled person will therefore understand that the logical function performed according to the second connection configuration C2 is the OR function between the first and second values.

The skilled person will also observe, as a corollary, that if the first and second values have complementary values of the first Vg and second Vd input potentials, with the complementary values being the opposite of the nominal values defined above, the logical function performed according to the second connection configuration C2 is then the NAND function between the first and second values, i.e. the complement of the OR function.

The second connection configuration C2 then enables performing the OR logical function or the NAND logical function.

In the embodiment example of FIG. 1, each respective block 12 of memory devices 14 is advantageously a block aimed exclusively at performing one of the logical functions among the aforementioned AND, NOR, OR and NAND logical functions. Each respective block 12 is then a block formed of memory devices 14 where the transistors 20 and ferroelectric capacitors 25 are connected according to the first connection configuration C1 to perform the AND or NOR function, or a block formed of memory devices 14 where the transistors 20 and ferroelectric capacitors 25 are connected according to the second connection configuration C2 to perform the OR and NAND function.

The skilled person will further understand that the connection configuration chosen, i.e. from among the first C1 and second C2 connection configurations, is variable from one block 12 to another within the electronic circuit 10, and that the values of the first Vg and second Vd input potentials applied by the programming device 16 from among the nominal values and the complementary values are also variable from one block 12 to another within said electronic circuit 10, so that the electronic circuit 10 according to the invention is advantageously configured to perform each of the logical functions from among the AND, NOR, OR, and NAND logical functions.

In a variant of the embodiment example of FIG. 1, not shown, the block 12 of memory devices 14 is made in the form of two sub-blocks, namely a first sub-block including the transistors 20 and a second sub-block, distinct from the first sub-block and including the ferroelectric capacitors 25, also with a selection switch connected in series with each ferroelectric capacitor 25. According to this variant, the transistors 20 are arranged in the form of a two-dimensional matrix within the first sub-block, and the respective sets each formed of the ferroelectric capacitor 25 and the selection switch connected in series are also arranged in the form of a two-dimensional matrix within the second sub-block. According to this variant, said block 12 further includes a connection module of the second sub-block to the first sub-block, the connection module including a multiplexer configured to select a connection configuration, for each memory device 14 formed of a transistor 20 of the first sub-block and of a ferroelectric capacitor 25 of the second sub-block, respectively, chosen from among the first connection configuration C1 and the second connection configuration C2.

This variant then enables a dynamic modification of the connection configuration between the first connection configuration C1 and the second connection configuration C2 for each block 12 during the implementation of the electronic circuit 10 according to the invention. The transition from one connection configuration to the other among the first C1 and second C2 connection configurations is carried out via an adapted control of the selection switches associated with the ferroelectric capacitors 25 in the second sub-block.

The skilled person will observe that the operation of the memory device 14 according to the invention is similar, whether the transistor 20 is a ferroelectric gate oxide field-effect transistor, i.e. FeFET, according to the embodiment examples of FIGS. 2 and 3, or whether the transistor 20 is a field-effect transistor with ferroelectric capacity connected to the gate electrode, i.e. FeMFET, in a variant not shown.

Thus, the memory device 14 according to the invention enables performing a logical function, namely the AND function or the NOR function according to the first connection configuration C1, and the respective OR function or NAND function according to the second connection configuration C2, this directly in the memory, i.e. a logical function of the AND, NOR, OR, or NAND type in the PIM, while having a limited consumption of current.

1. A memory device comprising:
a ferroelectric field-effect transistor including a gate electrode and first and second conduction electrodes;
a ferroelectric capacitor including first and second charge electrodes;
the transistor and the ferroelectric capacitor being connected according to a configuration chosen from a first connection configuration, wherein the first conduction electrode of the transistor is configured to be connected to a reference potential and the second conduction electrode is connected to the first charge electrode of the ferroelectric capacitor, and a second connection configuration, wherein the first conduction electrode of the transistor is connected to the first charge electrode of the ferroelectric capacitor and the second conduction electrode of the transistor is connected to the second charge electrode of the ferroelectric capacitor.

2. The memory device according to claim 1, wherein the transistor is chosen from the group consisting of a ferroelectric gate oxide field-effect transistor and a field-effect transistor with ferroelectric capacity connected to the gate electrode.

3. An electronic circuit comprising a plurality of memory devices, each according to claim 1.

4. The electronic circuit according to claim 3, wherein the electronic circuit comprises a substrate, a set of level(s) close to the substrate, called front end, for the connection of electronic component(s), and a set of level(s) distant from the substrate, called back end.

5. The electronic circuit according to claim 4, wherein the transistor is included in the front end, the ferroelectric capacitor being included in the back end.

6. The electronic circuit according to claim 4, wherein the transistor and the ferroelectric capacitor are included in the back end.

7. The electronic circuit according to claim 4, wherein, when the transistor is a field-effect transistor with ferroelectric capacity connected to the gate electrode further including an additional capacitor forming the ferroelectric capacity, then the additional capacitor is included in the back end.

8. The electronic circuit according to claim 3, wherein the electronic circuit comprises at least one block of several memory devices.

9. The electronic circuit according to claim 8, wherein a first block among the at least one block is formed of memory devices, where the transistors and ferroelectric capacitors are connected according to the first connection configuration, and a second block among the at least one block being formed of memory devices, where the transistors and ferroelectric capacitors are connected according to the second connection configuration.

10. The electronic circuit according to claim 8, wherein a block among the at least one block further includes a first sub-block including only the transistors, a second sub-block including only the ferroelectric capacitors, and a connection module of the second sub-block to the first sub-block, the connection module including a multiplexer to select a connection configuration, for each memory device formed of a transistor of the first sub-block and a ferroelectric capacitor of the second sub-block, chosen from the first connection configuration and the second connection configuration.

11. A method of programming a memory device according to claim 1, comprising a programming phase, during which a first input potential is applied to the gate electrode to write a first value, and a second input potential is applied to the second charge electrode to write a second value;
the first conduction electrode and the first charge electrode being further connected to a reference potential when the transistor and the ferroelectric capacitor are connected according to the second connection configuration.

12. The programming method according to claim 11, wherein, during the programming phase, the transistor is polarized at a low level if the first input potential is greater than a programming potential, and at a high level if the first input potential is less than the opposite of the programming potential.

13. The programming method according to claim 12, wherein, during the programming phase, the ferroelectric capacitor is polarized at a high level if the second input potential is greater than the programming potential, and at a low level if the second input potential is less than the opposite of the programming potential,
with the first input potential being between a threshold potential of the transistor and the programming potential when the transistor and the ferroelectric capacitor are connected according to the first connection configuration; and
with the first input potential less than the threshold potential of the transistor when the transistor and the ferroelectric capacitor are connected according to the second connection configuration.

14. A method of reading a memory device according to claim 1, the memory device being configured to perform a logical function between a first value and a second value previously written in the memory device via a programming method, the reading method comprising a reading phase, during which the gate electrode is connected to an electrical ground, and during which the opposite of the programming potential is applied to the second charge electrode, a result of the logical function corresponding to a current value through the memory device.

15. The reading method according to claim 14, wherein the result of the logical function is a binary value determined via the comparison of the current value through the memory device with a predefined current threshold.

16. The reading method according to claim 15, wherein the result of the logical function is equal to 1 if said current value is greater than the predefined current threshold, and 0 otherwise.

17. The reading method according to claim 14, wherein, when the transistor and the ferroelectric capacitor are connected according to the first connection configuration, the logical function is an AND function between the first and second values for nominal values of the first and second input potentials, and the logical function is a NOR function between the first and second values for complementary values of the first and second input potentials, the complementary values being the opposite of said nominal values.

18. The reading method according to claim 14, wherein, when the transistor and the ferroelectric capacitor are connected according to the second connection configuration, the logical function is an OR function between the first and second values for nominal values of the first and second input potentials, and the logical function is a NAND function between the first and second values for complementary values of the first and second input potentials, the complementary values being the opposite of said nominal values.

19. The reading method according to claim 14, wherein the first value, programmed in the transistor during the programming phase, corresponds to a level of transistor polarization resulting from the application of the first input potential to the gate electrode.

20. The reading method according to claim 14, wherein the second value, programmed in the ferroelectric capacitor during the programming phase, corresponds to a polarization level of the ferroelectric capacitor resulting from the application of the second input potential to the second charge electrode;
the first conduction electrode and the first charge electrode being further connected to a reference potential when the transistor and the ferroelectric capacitor are connected according to the second connection configuration.
